(19) United States
(12) Patent Application Publication
(10) Pub. No.: US 2026/0076102 A1
(43) Pub. Date: Mar. 12, 2026

(54) SEMICONDUCTOR-TYPE QUANTUM BIT DEVICE

(71) Applicant: NATIONAL INSTITUTE OF ADVANCED INDUSTRIAL SCIENCE AND TECHNOLOGY, Tokyo (JP)

(72) Inventors: Hidehiro Asai, Ibaraki (JP); Takahiro Mori, Ibaraki (JP); Toru Mogami, Ibaraki (JP)

(21) Appl. No.: 19/108,428

(22) PCT Filed: Jul. 11, 2023
(86) PCT No.: PCT/JP2023/025591

§ 371 Date: Jun. 6, 2025

(30) Foreign Application Priority Data
Sep. 5, 2022 (JP) 2022-141062

(51) Int. Cl. H10N 60/10; B82Y 10/00

(52) U.S. Cl. CPC H10N 60/128; H10N 60/11; B82Y 10/00

(57) ABSTRACT

The present invention has an object to provide a semiconductor-type quantum bit device in which, at the time of integration of a plurality of devices, characteristic variations of a quantum bit operation are suppressed. Provided is a semiconductor-type quantum bit device (10), comprising at least: a support substrate (1) formed of a first conductivity type semiconductor layer; a fringe electric field forming layer (2) formed on the support substrate (1), the fringe electric field forming layer (2) being formed of any one of a second conductivity type semiconductor layer and a metal layer, the second conductivity type semiconductor layer having a conductivity type different from a conductivity type of the first conductivity type semiconductor layer, the metal layer forming a Schottky barrier with the support substrate; a buried oxide layer (3) formed on the fringe electric field forming layer (2); and a quantum dot semiconductor layer (4) which is formed on the buried oxide layer (3) and in which quantum dots are formed.

### TECHNICAL FIELD

The present invention relates to a semiconductor-type quantum bit device in which characteristic variations of a quantum bit operation are suppressed by a fringe electric field.

### BACKGROUND ART

Quantum computers have been developed in various modes such as a superconducting type, an ion trap type, a photon type, and a semiconductor type. Among them, a semiconductor-type quantum bit device has compatibility with existing semiconductor device manufacturing equipment for classical computers, and studies on large-scale integration utilizing an integration technology cultivated in the classical computers have been conducted.

For example, there has been proposed a technology of highly integrating the semiconductor-type quantum bit devices by burying a small magnet required for a spin operation using electric dipole spin resonance (EDSR) in a semiconductor layer, thereby reducing a formation area per quantum bit (see Non-Patent Literature 1).

With this proposal, a single-qubit gate having an excellent quantum bit operation characteristic due to the arrangement of the small magnet, and an integrated circuit obtained by highly integrating the gates can be achieved.

Incidentally, for large-scale integration of the semiconductor-type quantum bit devices, in order to perform meaningful quantum computing operations with fewer errors, it is essential to suppress characteristic variations in the individual integrated semiconductor-type quantum bit devices in addition to the high integration.

Regarding this point, in the semiconductor-type quantum bit device, similarly to a classical transistor and the like, when variations are caused in device dimensions during a manufacturing process, the individual devices also vary in quantum bit operations. Particularly, in the semiconductor-type quantum bit device, even slight dimensional variations on the order of several nanometers cause large variations of the quantum bit operation.

It is difficult to avoid the occurrence of slight dimensional variations even through use of the most-advanced manufacturing equipment, and hence it is required to develop a new technology capable of suppressing, even when there is a dimensional variation, individual characteristic variations at the time of integration of a plurality of devices.

### CITATION LIST

### Non-Patent Literature

### [NPL 1]

S. Iizuka et al., VLSI Tech. Dig. 2021, JFS5-5.

### SUMMARY OF INVENTION

### Technical Problem

The present invention has an object to solve the problems in the related art, and to accomplish the following purposes. That is, the present invention has an object to provide a semiconductor-type quantum bit device in which, at the time of integration of a plurality of devices, characteristic variations of a quantum bit operation are suppressed.

### Solution to Problem

The present invention is based on the above-mentioned findings and means for achieving the object are as follows. That is,

<1> A semiconductor-type quantum bit device, including at least: a support substrate formed of a first conductivity type semiconductor layer; a fringe electric field forming layer formed on the support substrate, the fringe electric field forming layer being formed of any one of a second conductivity type semiconductor layer and a metal layer, the second conductivity type semiconductor layer having a conductivity type different from a conductivity type of the first conductivity type semiconductor layer, the metal layer forming a Schottky barrier with the support substrate; a buried oxide layer formed on the fringe electric field forming layer; and a quantum dot semiconductor layer which is formed on the buried oxide layer and in which quantum dots are formed.

<2> The semiconductor-type quantum bit device according to the above-mentioned Item <1>, further including a back gate electrode configured to apply a voltage to the support substrate.

<3> The semiconductor-type quantum bit device according to the above-mentioned Item <1> or <2>, wherein the buried oxide layer has a thickness of from 10 nm to 100 nm.

<4> The semiconductor-type quantum bit device according to any one of the above-mentioned Items <1> to <3>, wherein the quantum dot semiconductor layer is formed into an elongated band shape in a top view, and the elongated band has a width in a transverse direction of 100 nm at longest.

<5> The semiconductor-type quantum bit device according to any one of the above-mentioned Items <1> to <4>, wherein the quantum dot semiconductor layer has a thickness of from 2.5 nm to 50 nm.

<6> The semiconductor-type quantum bit device according to any one of the above-mentioned Items <1> to <5>, wherein the support substrate has a first conductivity type impurity concentration of 1×10¹⁹ cm⁻³ or more, and wherein the fringe electric field forming layer is formed of the second conductivity type semiconductor layer, and has a second conductivity type impurity concentration of 1×10¹⁹ cm⁻³ or more.

<7> The semiconductor-type quantum bit device according to the above-mentioned Item <6>, wherein the support substrate is formed of Si, and wherein the second conductivity type semiconductor layer is formed of Si.

<8> The semiconductor-type quantum bit device according to any one of the above-mentioned Items <1> to <7>, wherein the quantum dot semiconductor layer is formed of any one of Si, SiGe and Ge.

<9> The semiconductor-type quantum bit device according to any one of the above-mentioned Items <1> to <8>, wherein the buried oxide layer is formed of any one of SiO₂ and GeO₂.

<10> The semiconductor-type quantum bit device according to any one of the above-mentioned Items <1> to <9>, further including at least: a structure unit in which three barrier gate electrodes and two plunger gate electrodes are formed above the quantum dot semiconductor layer through a gate insulating layer, each of the two plunger gate electrodes being arranged between adjacent two of the three barrier gate electrodes so as to be spaced apart from the adjacent two of the three barrier gate electrodes, the quantum dots being formed at two positions opposed to the two plunger gate electrodes of the quantum dot semiconductor layer; and a static magnetic field applying unit configured to apply a static magnetic field to the quantum dots.

### Advantageous Effects of Invention

According to the present invention, it is possible to solve the problems in the related art and provide the semiconductor-type quantum bit device in which, at the time of integration of the plurality of devices, characteristic variations of the quantum bit operation are suppressed.

### BRIEF DESCRIPTION OF DRAWINGS

FIG. 1(a) is a perspective view for illustrating a basic configuration of a semiconductor-type quantum bit device of the present invention.

FIG. 1(b) is a cross-sectional view taken along the y-z plane of FIG. 1(a).

FIG. 2(a) is a perspective view for illustrating a configuration example of a semiconductor-type spin quantum bit device.

FIG. 2(b) is a cross-sectional view taken along the y-z plane of FIG. 2(a).

FIG. 3 is an explanatory graph for showing a problem of a dimensional deviation at the time of a SWAP gate operation.

FIG. 4(a) is a perspective view for illustrating a configuration example of a semiconductor-type charge quantum bit device.

FIG. 4(b) is an explanatory view (1) for illustrating a single-qubit gate operation in the semiconductor-type charge quantum bit device.

FIG. 4(c) is an explanatory view (2) for illustrating the single-qubit gate operation in the semiconductor-type charge quantum bit device.

FIG. 5(a) is a perspective view for illustrating the outline of the semiconductor-type spin quantum bit device related to settings of a simulation test.

FIG. 5(b) is an explanatory view for illustrating a configuration taken along the y-z plane of FIG. 5(a).

FIG. 5(c) is an explanatory top view for illustrating a configuration taken along the x-y plane of FIG. 5(a).

FIG. 6 shows graphs of calculation results of exchange interactions (Jₑₓ) for a “P substrate” condition in a comparative test target device and an “N/P substrate” condition and an “N/P substrate & V_{sub}=0.3 V” condition in a test target device.

FIG. 7 is a graph for showing calculation results of SWAP operation fidelity.

FIG. 8 is an explanatory graph for showing a relationship between the exchange interaction between two quantum bits and a potential barrier area.

FIG. 9 is a diagram for showing potential distributions in the y-z plane in the test target device and the comparative test target device.

FIG. 10 is a diagram for showing an electron density distribution in bit 1 and bit 2 based on wave functions of electrons in bit 1 and bit 2.

FIG. 11 shows graphs of relationships between ΔW and Δd_{B}, Δh_{B} and ΔS_{B} normalized by d_{B}, h_{B} and S_{B}, respectively.

### DESCRIPTION OF EMBODIMENTS

### (Semiconductor-Type Quantum Bit Device)

First, a basic configuration of a semiconductor-type quantum bit device of the present invention is described with reference to the drawings.

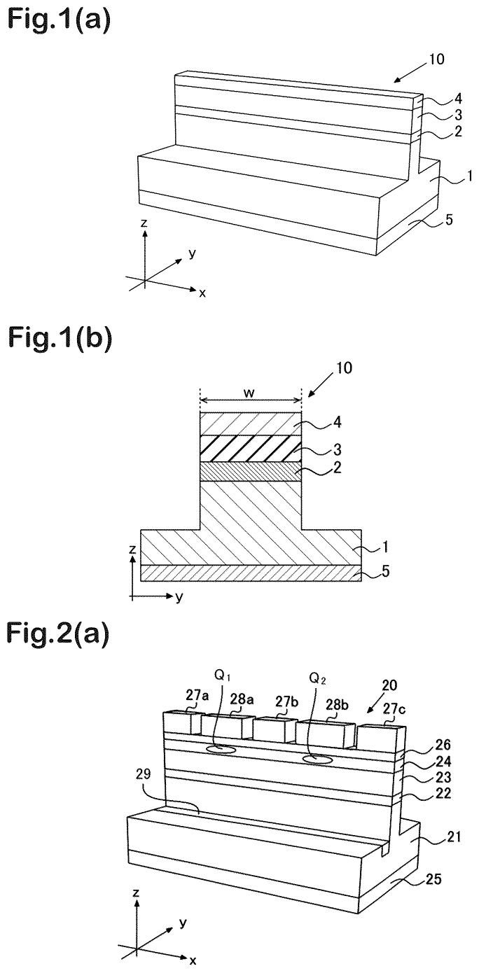

FIG. 1(a) is a perspective view for illustrating the basic configuration of the semiconductor-type quantum bit device of the present invention, and FIG. 1(b) is a cross-sectional view taken along the y-z plane of FIG. 1(a).

As illustrated in FIG. 1(a) and FIG. 1(b), a semiconductor-type quantum bit device 10 includes at least a support substrate 1, a fringe electric field forming layer 2, a buried oxide layer 3, a quantum dot semiconductor layer 4 and a back gate electrode 5.

The support substrate 1 is formed of a first conductivity type semiconductor layer.

A material for forming the support substrate 1 is not particularly limited, and examples of the material include publicly known semiconductor substrates. Among them, silicon (Si) is preferred from viewpoints of processability and availability.

Examples of impurities for providing the first conductivity type include, in the case of a P type, publicly known impurities such as boron (B), and, in the case of an N type, publicly known dopant materials such as phosphorus (P). The first conductivity type semiconductor layer can be obtained by, for example, at the time of manufacturing an ingot material by a Czochralski method, adding those dopant materials to a melt of a semiconductor material such as Si, and the support substrate 1 can be obtained by cutting out this ingot material into a target size.

An impurity concentration for the first conductivity type in the support substrate 1 is not particularly limited and is preferably 1×10¹⁹ cm⁻³ or more, more preferably 1×10²⁰ cm⁻³ or more. When the impurity concentration is excessively low, the intensity of a fringe electric field obtained by arranging the fringe electric field forming layer 2 may become insufficient. The upper limit of the impurity concentration for the first conductivity type is about 1×10²¹ cm⁻³.

The fringe electric field forming layer 2 is a layer formed on the support substrate 1.

Formation of the fringe electric field forming layer 2 on the support substrate 1 allows generation of a fringe electric field which is curved and routed around from an outer edge corner portion extending in a longitudinal direction (in the figure, an x direction) of an upper surface of the fringe electric field forming layer 2 toward the buried oxide layer 3 in an internal direction (in the figure, a y direction) of the upper surface of the fringe electric field forming layer 2.

One configuration for generating such a fringe electric field is a configuration in which the fringe electric field forming layer 2 is formed of a second conductivity type semiconductor layer having a conductivity type different from the conductivity type of the first conductivity type semiconductor layer.

Materials for forming the second conductivity type semiconductor layer are not particularly limited, and examples of the materials include publicly known semiconductor substrates. Among them, silicon (Si) is preferred from viewpoints of processability and availability.

Impurities for providing the second conductivity type are impurities having a polarity opposite to that of the impurities for providing the first conductivity type, and examples of the impurities include, in the case of the P type, publicly known impurities such as B, and, in the case of the N type, publicly known dopant materials such as P. The second conductivity type semiconductor layer can be obtained by publicly known forming methods such as a method of ion-implanting those dopant materials and a method of forming an epitaxial growth layer to which the dopant materials are added.

An impurity concentration for the second conductivity type in the second conductivity type semiconductor layer is not particularly limited, and is preferably 1×10¹⁹ cm⁻³ or more, more preferably 1×10²⁰ cm⁻³ or more. When the impurity concentration is excessively low, the intensity of the fringe electric field obtained by arranging the fringe electric field forming layer 2 may become insufficient. The upper limit of the impurity concentration for the second conductivity type is about 1×10²¹ cm⁻³.

When the fringe electric field forming layer 2 is formed of the second conductivity type semiconductor layer, the support substrate 1 and the fringe electric field forming layer 2 can be formed through use of a publicly known N/P substrate or a publicly known P/N substrate, and the manufacturing process can be simplified.

In particular, when the support substrate 1 is formed of Si and the fringe electric field forming layer 2 is formed of the second conductivity type semiconductor layer formed of Si, the support substrate 1 and the fringe electric field forming layer 2 can be formed through use of a general-purpose N/P substrate made of Si or a general-purpose P/N substrate made of Si.

When the semiconductor-type quantum bit device 10 is formed as an electron-type quantum bit device using electrons as a semiconductor carrier, the conductivity type of the first conductivity type semiconductor layer (support substrate 1) is set to the P type, and the conductivity type of the second conductivity type semiconductor layer (fringe electric field forming layer 2) is set to the N type. Meanwhile, when the semiconductor-type quantum bit device 10 is formed as an hole-type quantum bit device using holes as a semiconductor carrier, the conductivity type of the first conductivity type semiconductor layer (support substrate 1) is set to the N type, and the conductivity type of the second conductivity type semiconductor layer (fringe electric field forming layer 2) is set to the P type.

Another configuration for generating the fringe electric field is a configuration in which the fringe electric field forming layer 2 is formed of a metal layer for forming a Schottky barrier between the fringe electric field forming layer 2 and the support substrate 1.

In order to form a Schottky barrier between the fringe electric field forming layer 2 and the support substrate 1, the metal layer may be formed so as to have a work function equivalent to that of the second conductivity type semiconductor layer.

That is, in order to obtain the fringe electric field, the metal layer is required to take over the role of the second conductivity type semiconductor layer in the N/P substrate configuration or the P/N substrate configuration including the support substrate 1 and the second conductivity type semiconductor layer.

For example, in terms of a Fermi level for controlling the work function, when the second conductivity type semiconductor layer is formed of silicon, the Fermi level when the conductivity type is the N type is from about 4.0 eV to about 4.3 eV, and the Fermi level when the conductivity type is the P type is from about 4.8 eV to about 5.1 eV. The same holds true also for the Fermi level when the support substrate 1 (the first conductivity type semiconductor layer) is formed of silicon.

From those relationships, the material for forming the metal layer (which takes over the role of the P-type semiconductor layer) when the support substrate 1 is formed of the N-type silicon semiconductor layer is only required to be a metal material having a Fermi level of from about 4.6 eV to about 6.0 eV, and examples of the material include gold (Au) and platinum (Pt). Further, the material for forming the metal layer (which takes over the role of the N-type semiconductor layer) when the support substrate 1 is formed of the P-type silicon semiconductor layer is only required to be a metal material having a Fermi level of from about 3.0 eV to about 4.4 eV, and examples of the material include aluminum (Al) and tungsten (W).

A method of forming the metal layer is not particularly limited, and examples of the method include a publicly known vapor deposition method and a publicly known CVD method.

The buried oxide layer 3 is a layer formed on the fringe electric field forming layer 2.

The buried oxide layer 3 is not particularly limited and is preferred to be formed of any one of SiO₂ and GeO₂ because the buried oxide layer 3 can be easily formed from those materials through use of existing manufacturing equipment.

A method of forming the buried oxide layer 3 is not particularly limited, and a publicly known BOX layer forming method in a SOI substrate can be applied.

A thickness of the buried oxide layer 3 (thickness in an up-down direction (in the figure, a z direction)) is preferred to be from 10 nm to 100 nm. When the thickness is less than 10 nm, it becomes difficult for the fringe electric field to enter the buried oxide layer 3, and, when the thickness is more than 100 nm, the fringe electric field that has entered the buried oxide layer 3 may be unified to reduce the influence on the quantum dot semiconductor layer 4.

The quantum dot semiconductor layer 4 is formed on the buried oxide layer 3 and is a layer in which quantum dots are formed.

A material for forming the quantum dot semiconductor layer 4 is not particularly limited as long as the material is a semiconductor material and is preferred to be formed of any one of Si, germanium (Ge) and SiGe being a mixed crystal thereof, because the quantum dot semiconductor layer 4 can be easily formed from those materials through use of the existing manufacturing equipment.

A method of forming the quantum dot semiconductor layer 4 is not particularly limited, and a publicly known SOI layer forming method in the SOI substrate and a method conforming thereto can be applied.

The quantum dot semiconductor layer 4 may be any one of the first conductivity type and the second conductivity type, and, to provide those conductivity types, matters described for the first conductivity type semiconductor layer and the second conductivity type semiconductor layer can be applied.

Further, an impurity concentration in the quantum dot semiconductor layer 4 is not particularly limited and is from about 1×10¹¹ cm⁻³ to about 1×10¹⁸ cm⁻³.

The quantum dot semiconductor layer 4 is formed into an elongated band shape in a top view (in the figure, in the x-y top view) in order to form a dot string of a plurality of quantum dots along a longitudinal direction (in the figure, the x direction) of the band. A width (W) of the elongated band in a short direction (in the figure, the y direction) is not particularly limited, and is preferred to be 100 nm or less. When the width (W) is more than 100 nm, it may be difficult to form the quantum dots. The lower limit of the width (W) is about 2 nm.

A thickness of the quantum dot semiconductor layer 4 (thickness in the up-down direction (in the figure, the z direction)) is not particularly limited, and is preferred to be from 2.5 nm to 50 nm. When the thickness is less than 2.5 nm, it may become difficult to obtain a device characteristic as designed, and, when the thickness is more than 50 nm, it may become difficult for the fringe electric field to affect the quantum dots because the fringe electric field is blocked by the body of the thick quantum dot semiconductor layer 4.

The quantum dot and a quantum bit formed of the quantum dot are formed due to arrangement of electrodes formed on the quantum dot semiconductor layer 4 through a gate insulating layer and voltage control.

By addition of the configurations of those electrodes, the configuration of the semiconductor-type quantum bit device 10 can be applied to both of a spin quantum bit device and a charge quantum bit device which are to be described later.

Further, an electric field that is based on the gate insulating layer and the electrode provides the fringe electric field around the fringe electric field forming layer 2.

In the semiconductor-type quantum bit device 10, a trench structure is provided. The trench structure is obtained by cutting in the x direction from the quantum dot semiconductor layer 4 to a middle position of the support substrate 1. With the trench structure, the widths of the buried oxide layer 3 and the fringe electric field forming layer 2 in the short direction can be controlled in accordance with the width (W) of the quantum dot semiconductor layer 4 in the short direction.

A method of forming the trench structure is not particularly limited, and examples of the method include a publicly known lithography processing method.

In the illustrated example of the semiconductor-type quantum bit device 10, the plurality of quantum dots can be formed along the longitudinal direction (x direction) of the quantum dot semiconductor layer 4 formed into the elongated band shape in a top view so that a one-dimensional quantum bit string can be formed. However, a two-dimensional quantum bit string can be also easily formed by forming the quantum dot semiconductor layer 4 having the elongated band shape and the buried oxide layer 3 and the fringe electric field forming layer 2 that have the same elongated band shape in the y direction in addition to the x direction and crossing those elongated bands with each other.

The configuration of those quantum bit strings can be achieved by any structure in accordance with a publicly known integration technology, and the technical idea of the present invention is not limited to the illustrated example. Further, in the illustrated example, a two-qubit gate single element structure is illustrated, but large-scale integration is possible by applying a plurality of two-qubit gate structures to the quantum bit string.

The back gate electrode 5 is an electrode capable of applying a voltage to the support substrate 1. As the arrangement of the back gate electrode 5, although not limited to the illustrated example, when the back gate electrode 5 is formed as an electrode layer to be formed on a surface of the support substrate 1 on a side opposite to a surface on a side on which the fringe electric field forming layer 2 is formed, wiring structure of the semiconductor-type quantum bit device 10 can be simplified.

The back gate electrode 5 is an optional structure in the semiconductor-type quantum bit device 10, but, as verified in the section of Examples later, the back gate electrode 5 brings about an effect of significantly reducing the characteristic variations of the quantum bit operation.

A method of forming the back gate electrode 5 is not particularly limited, and the back gate electrode 5 can be formed through selection from publicly known electrode materials and electrode layer forming methods as appropriate.

### First Embodiment: Semiconductor-Type Spin Quantum Bit Device

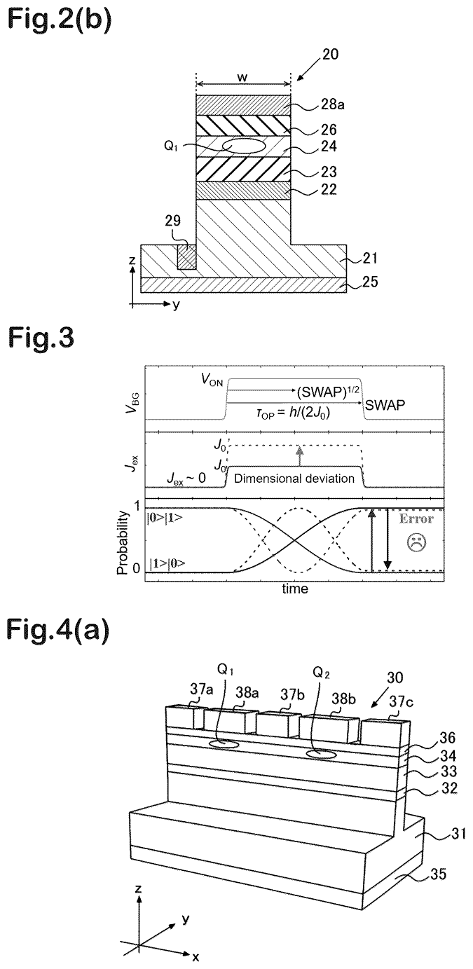

With reference to FIG. 2(a) and FIG. 2(b), an example in which the semiconductor-type quantum bit device of the present invention is formed as a spin quantum bit device capable of performing a two-qubit gate operation is described as a first embodiment.

FIG. 2(a) is a perspective view for illustrating a configuration example of the semiconductor-type spin quantum bit device, and FIG. 2(b) is a cross-sectional view taken along the y-z plane of FIG. 2(a).

As illustrated in FIG. 2(a) and FIG. 2(b), in a semiconductor-type spin quantum bit device 20, in addition to a support substrate 21, a fringe electric field forming layer 22, a buried oxide layer 23, a quantum dot semiconductor layer 24 and a back gate electrode 25 formed similarly to the support substrate 1, the fringe electric field forming layer 2, the buried oxide layer 3, the quantum dot semiconductor layer 4 and the back gate electrode 5 in the semiconductor-type quantum bit device 10, three barrier gate electrodes 27a, 27b and 27c and two plunger gate electrodes 28a and 28b are formed on the quantum dot semiconductor layer 24 through a gate insulating layer 26.

Further, the semiconductor-type spin quantum bit device 20 includes a static magnetic field applying unit (not shown) and a buried magnet layer 29.

The plunger gate electrode 28a (28b) is arranged between two adjacent barrier gate electrodes 27a and 27b (27b and 27c) so as to be spaced apart from the barrier gate electrodes 27a and 27b (27b and 27c).

The barrier gate electrodes 27a, 27b and 27c and the plunger gate electrodes 28a and 28b act on the behavior of a semiconductor carrier (electrons or holes, description is hereinafter made assuming electrons as a model) in two quantum dot regions of the quantum dot semiconductor layer 24, and quantum dots Q₁ and Q₂ are formed at two positions opposed to the plunger gate electrodes 28a and 28b of the quantum dot semiconductor layer 24.

Further, in the two-qubit gate operation, the plunger gate electrodes 28a and 28b change the potentials of the quantum dots Q₁ and Q₂ to control the electron count states in the dots, and the barrier gate electrodes 27a, 27b and 27c have the role of changing a tunnel barrier (potential barrier) between the quantum dots Q₁ and Q₂ to control an exchange interaction between the two quantum bits.

In the semiconductor-type spin quantum bit device 20, the two-qubit gate operation is executed by using the exchange interaction between the two quantum bits, and hence, when a distance between the quantum dots Q₁ and Q₂ is excessively large, a trouble may be caused in execution of the two-qubit gate operation.

Accordingly, it is preferred to appropriately set elements for controlling the distance between the quantum dots Q₁ and Q₂.

Specifically, it is preferred that a length of each of the plunger gate electrodes 28a and 28b in a direction (in the figure, the x direction) along the longitudinal direction of the quantum dot semiconductor layer 24 be from 2 nm to 100 nm, and it is preferred that a length of each of the barrier gate electrodes 27a, 27b and 27c in the direction along the longitudinal direction of the quantum dot semiconductor layer 24 be from 2 nm to 100 nm. Further, it is preferred that a separation distance between the plunger gate electrode 28a (28b) and each of the two barrier gate electrodes 27a and 27b (27b and 27c) adjacent thereto be from 2 nm to 50 nm.

Methods of forming the gate insulating layer 26, the barrier gate electrodes 27a, 27b and 27c and the plunger gate electrodes 28a and 28b are not particularly limited, and those layers and electrodes can be formed by applying publicly known gate electrode materials and gate electrode forming methods for classical CMOS transistors and the like.

The static magnetic field applying unit is a unit capable of applying a static magnetic field to the quantum dots Q₁ and Q₂ and the buried magnet layer 29. The static magnetic field is uniform across the entire device.

When a static magnetic field B₀ is applied from the static magnetic field applying unit to localized levels taken by the electrons confined in the quantum dots Q₁ and Q₂, Zeeman splitting in which the energy level splits with an energy difference of gμ_{B}B₀ (μ_{B}: Bohr magneton, g: g factor of electron spin) occurs, and, in the quantum dots Q₁ and Q₂, a quantum two-level system represented by two quantum states of |0> state and |1> state is generated.

The static magnetic field applying unit is not particularly limited and can be selected as appropriate from a publicly known member formed of a magnet and a coil.

In the semiconductor-type spin quantum bit device 20 formed as described above, through the voltage control of the barrier gate electrodes 27a, 27b and 27c, the tunnel barrier between the quantum dots Q₁ and Q₂ is changed so that the exchange interaction is given between the two quantum bits. Thus, a SWAP gate operation that is the two-qubit gate operation can be performed.

In this case, the exchange interaction means an action in which, when two electrons present one by one in the respective quantum dots Q₁ and Q₂ overlap each other on an electron orbital, the two electrons affect each other in electron spin, and an energy Jₑₓ of the exchange interaction is given as an energy difference between a case in which the spin orientations are aligned and a case in which the spin orientations are alternate.

The specific SWAP gate operation is executed by giving an exchange interaction of an appropriate magnitude to the initial two-quantum state |0>|1> (or |1>|0>) in the quantum dots Q₁ and Q₂, thereby flipping the quantum states so as to exchange (swap) the quantum states and achieving a two-quantum state |1>|0> (or |0>|1>).

That is, as illustrated in FIG. 3, the magnitude of the exchange interaction (Jₑₓ) is involved in the execution of the SWAP gate operation, and constant voltage (V_{BG}) control to the barrier gate electrodes 27a, 27b and 27c is performed using the magnitude of the exchange interaction (Jₑₓ) as a reference (J₀).

At this time, when a dimensional deviation (ΔW) is present in the width (W) of the quantum dot semiconductor layer 24 in the short direction, in a configuration set without consideration of the dimensional deviation, the magnitude of the exchange interaction (Jₑₓ) changes from the reference (changes from J₀ to J₀′). As a result, the initial two-quantum state |0>|1> (or |1>|0>) is not flipped to the two-quantum state of |1>|0> (or |0>|1>), and the SWAP gate operation results in an error.

However, in the semiconductor-type spin quantum bit device 20, the fringe electric field caused by arranging the fringe electric field forming layer 22 compensates for the dimensional deviation (ΔW) so as to bring the exchange interaction (Jₑₓ) closer to J₀ being the reference from J₀′.

Accordingly, when a plurality of two-qubit gate structures formed of the semiconductor-type spin quantum bit devices 20 are integrated, even when there is a dimensional deviation (ΔW) between those structures, due to the compensation action by the fringe electric field forming layer 22, the characteristic variations are suppressed, and a SWAP gate operation having few errors with the constant voltage (V_{BG}) control can be executed.

FIG. 3 is an explanatory graph for showing the problem of the dimensional deviation at the time of the SWAP gate operation.

The description with reference to FIG. 2(a) and FIG. 2(b) is resumed.

The buried magnet layer 29 is a layer buried in a recessed portion formed in a bottom portion (trench groove) of the trench structure of the support substrate 21.

A material for forming the buried magnet layer 29 is not particularly limited, and examples of the material include publicly known magnetic materials to be magnetized by an external magnetic field applied from the static magnetic field applying unit. Among them, it is preferred that the material be a magnetic material containing at least one of iron, cobalt, nickel and manganese.

Further, a method of forming the buried magnet layer 29 is not particularly limited, and examples of the method include a method being a combination of a publicly known lithography processing method of forming the recessed portion and a publicly known CVD method, ALD method or CMP method of forming the buried magnet layer 29 in the recessed portion.

The buried magnet layer 29 is magnetized by the static magnetic field B₀ applied from the static magnetic field applying unit to form magnetization M. The magnetization M caused locally in this magnet part forms a gradient magnetic field B_{SL} in which a magnetic field intensity is spatially changed at the positions of the quantum dots Q₁ and Q₂.

When an alternating voltage is applied to the plunger gate electrode 28a (or 28b) under this state, the center of gravity of the electron in the quantum dot Q₁ (or Q₂) vibrates in the gradient magnetic field B_{SL} so that the electron effectively feels the vibration of a transverse magnetic field component perpendicular to B₀, thereby being capable of performing quantum-mechanical transition between two levels of spin-up and spin-down. That is, the electron spin operation is controlled by an electrical signal supplied via the plunger gate electrode 28a (or 28b) so that a single-qubit gate (X gate) operation can be executed.

The buried magnet layer 29 is an optional member for executing such a single-qubit gate operation, and, through arrangement of the buried magnet layer 29, in the semiconductor-type spin quantum bit device 20, the single-qubit gate operation can be simultaneously achieved in addition to the two-qubit gate operation.

Any quantum computing operation can be executed by using, as one element, a universal gate set obtained by combining the single-qubit gate and the two-qubit gate and combining the elements. In this sense, the configuration of the semiconductor-type spin quantum bit device 20 capable of constructing a universal gate set in consideration of characteristic variations has a very important technical meaning for achieving any quantum computing operation.

The magnet for forming the buried magnet layer 29 is only required to be a magnet which forms the gradient magnetic field B_{SL} at the positions of the quantum dots Q₁ and Q₂ and may be arranged at a different position.

Further, as the single-qubit gate operation for the quantum dots Q₁ and Q₂, in addition to the spin operation method obtained by electric dipole spin resonance (EDSR) using the gradient magnetic field caused by the magnet, there can be also applied a spin operation method obtained by electric spin resonance (ESR) in which microwaves are transmitted via a wire to the quantum dot Q₁ (or Q₂) to vibrate the electron in the quantum dot Q₁ (or Q₂). The further modification example based on the electric spin resonance can be given to the semiconductor-type spin quantum bit device 20.

### Second Embodiment: Semiconductor-Type Charge Quantum Bit Device

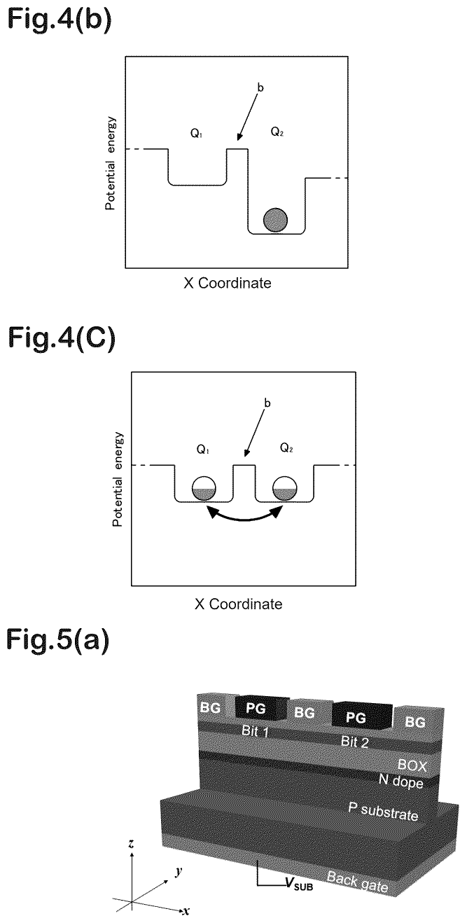

With reference to FIG. 4(a) to FIG. 4(c), an example in which the semiconductor-type quantum bit device of the present invention is formed as a charge quantum bit device is described as a second embodiment.

FIG. 4(a) is a perspective view for illustrating a configuration example of the semiconductor-type charge quantum bit device, and FIG. 4(b) and FIG. 4(c) are explanatory views for illustrating the single-qubit gate operation in the semiconductor-type charge quantum bit device.

As illustrated in FIG. 4(a), a semiconductor-type charge quantum bit device 30 includes, as a basic structure, a support substrate 31, a fringe electric field forming layer 32, a buried oxide layer 33, a quantum dot semiconductor layer 34 and a back gate electrode 35 formed similarly to the support substrate 1, the fringe electric field forming layer 2, the buried oxide layer 3, the quantum dot semiconductor layer 4 and the back gate electrode 5 in the semiconductor-type quantum bit device 10.

Further, the semiconductor-type charge quantum bit device 30 includes a gate insulating layer 36, barrier gate electrodes 37a, 37b and 37c and plunger gate electrodes 38a and 38b formed similarly to the gate insulating layer 26, the barrier gate electrodes 27a, 27b and 27c and the plunger gate electrodes 28a and 28b in the semiconductor-type spin quantum bit device 20.

In short, the semiconductor-type charge quantum bit device 30 has a configuration obtained by excluding, from the semiconductor-type spin quantum bit device 20, the static magnetic field applying unit and the buried magnet layer 29 which are not required for the device operation of the charge quantum bit device.

The semiconductor-type charge quantum bit device 30 and the semiconductor-type spin quantum bit device 20 are basically common in including a structure unit including at least two quantum dots (Q₁ and Q₂) formed in the common quantum dot semiconductor layer (24, 34) and various electrodes described above corresponding to the quantum computing operation performed by those two quantum dots, and in being capable of integrating a plurality of the structure units in one device.

However, while quantum information of the quantum two-level system in the semiconductor-type spin quantum bit device 20 is defined by the spin states (spin-up and spin-down) of the electrons in the quantum dots (Q₁ and Q₂), in the semiconductor-type charge quantum bit device 30, the quantum information of the quantum two-level system is defined by a presence state of the electron present in any one of the two quantum dots (Q₁ and Q₂).

That is, in the semiconductor-type charge quantum bit device 30, through voltage control with respect to the barrier gate electrodes 37a, 37b and 37c, a structure of two quantum dots (Q₁ and Q₂) is created, and, through voltage control with respect to the plunger gate electrodes 38a and 38b, a probability at which one electron is present in any one of the quantum dots (Q₁ and Q₂) is controlled.

Specifically, first, after the quantum dots are formed by adjusting the voltage of the barrier gate electrodes 27a, 27b and 27c, the voltage of the plunger gate electrodes 38a and 38b is controlled. Thus, control is performed so that one electron is present in any one of the quantum dots (see FIG. 4(b)).

Next, a pulse voltage is applied for a certain time period to the plunger gate electrodes 38a and 38b so that the levels of the two quantum dots (Q₁ and Q₂) are aligned, and control is performed so that the electrons can come and go between the levels through tunnel transition only during this period (see FIG. 4(c)).

In this manner, in the semiconductor-type charge quantum bit device 30, the electrons transition between the two levels in the quantum two-level system (the quantum dot Q₁ on the left and the quantum dot Q₂ on the right), and quantum information in which those two levels and an overlapping state thereof are added can be defined. That is, the single-qubit gate (X gate) operation is executed by controlling the presence state of the electron with respect to the two quantum dots (Q₁ and Q₂) by an electrical signal supplied via the plunger gate electrodes 38a and 38b.

In this case, the operation time period of the X gate operation (see FIG. 4(c)) is controlled by the magnitude of the potential barrier between the two quantum dots (Q₁ and Q₂) indicated in the figure by “b”, and is determined with reference to the time at which the width (W) of the quantum dot semiconductor layer 34 in the short direction has no dimensional deviation (ΔW).

Actually, when integration of the single-qubit gates (X gates) by a plurality of quantum dot semiconductor layers 34 (X gate strings) is performed with respect to a common electrode structure, each X gate structure more or less has a dimensional deviation (ΔW).

As a result, in a configuration set without consideration of this dimensional deviation (ΔW), the magnitude of the potential barrier changes from the reference, and different X gates vary in characteristics, resulting in that the computing results include an error.

However, in the semiconductor-type charge quantum bit device 30, the fringe electric field generated by arranging the fringe electric field forming layer 32 compensates for the deviation of the magnitude of the potential barrier that is based on the dimensional deviation (ΔW) to come closer to the reference.

That is, the starting point for considering the characteristic variations in the semiconductor-type charge quantum bit device 30 lies in the deviation of the magnitude of the potential barrier between the two quantum dots (Q₁ and Q₂) from the reference. This is the same origin as the starting point for considering the characteristic variations in the semiconductor-type spin quantum bit device 20. Thus, for the same reason as the reason described for the semiconductor-type spin quantum bit device 20, the deviation of the magnitude of the potential barrier from the reference receives the compensation action obtained by the fringe electric field.

Accordingly, even when the semiconductor-type charge quantum bit device 30 is formed by integrating a plurality of X gate structures having dimensional deviations (ΔW), with the compensation action obtained by the fringe electric field forming layer 32, the characteristic variations are suppressed, and the X gate operation having few errors can be executed.

### EXAMPLES

In order to verify the effectiveness and suitable conditions of the present invention, a simulation test was performed for the quantum mechanical interaction (exchange interaction) between two quantum bits and the fidelity of the two-qubit gate (SWAP gate) operation.

### <Test Conditions>

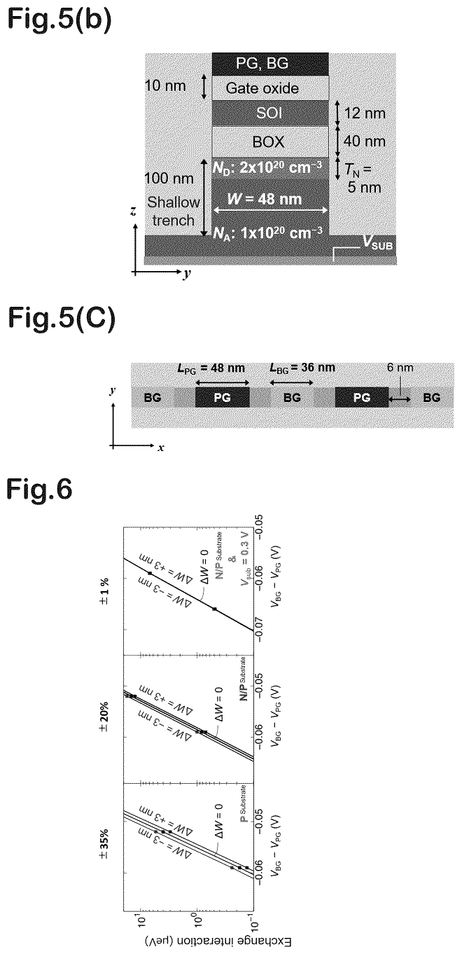

The simulation test was carried out basically assuming a MOS-type Si spin quantum bit device (test target device) illustrated in FIG. 5(a) to FIG. 5(c). FIG. 5(a) is a perspective view for illustrating the outline of the semiconductor-type spin quantum bit device with the settings of the simulation test, FIG. 5(b) is an explanatory view for illustrating a configuration taken along the y-z plane of FIG. 5(a), and FIG. 5(c) is an explanatory top view for illustrating a configuration taken along the x-y plane of FIG. 5(a).

This test target device is formed to conform to the semiconductor-type quantum bit device according to the basic configuration illustrated in FIG. 1. On a back gate (Back gate) electrode, a support substrate (N/P substrate) obtained by stacking a P-type support layer (P substrate) and an N-type support layer (N dope) is stacked. On the support substrate, a BOX layer and a SOI layer are stacked. At predetermined positions on the SOI layer, plunger gate (PG) electrodes and barrier gate (BG) electrodes are formed through a gate oxide (Gate oxide) layer.

The back gate electrode is formed of an aluminum (Al) electrode and is set so that a voltage (V_{sub}) can be applied thereto from an external power supply.

The P-type support layer is set as a Si layer having an acceptor density of 1×10²⁰ cm⁻³.

The N-type support layer is set as a Si layer having a donor density of 2×10²⁰ cm⁻³ and a thickness in the z direction of 5 nm.

In those P-type support layer and N-type support layer, a trench structure is formed, and a groove depth of a trench groove formed from an upper surface position of the N-type support layer along the z direction toward a bottom surface side of the P-type support layer is set to 100 nm.

Further, the width (W) of each of the P-type support layer and the N-type support layer in the y direction remaining after the trench groove is formed is set to 48 nm. In this manner, the width (W) in the y direction of each of the BOX layer, the SOI layer, the gate oxide layer, the PG electrodes and the BG electrodes formed on the N-type support layer is also set to 48 nm. In this simulation test, with reference to this width in the y direction (W=48 nm) as a basis, some numerical changes (ΔW) are given, and the influence thereof is checked.

The BOX layer is a SiO₂ layer formed as a buried oxide layer, and a thickness thereof in the z direction is set to 40 nm.

The SOI layer is a Si layer formed as a Si layer formed on an insulating layer (Silicon on Insulator), and a thickness thereof in the z direction is set to 12 nm. In this SOI layer, through voltage control with respect to the PG electrodes and the BG electrodes, quantum dots forming two quantum bits of bit 1 and bit 2 (Bit 1 and Bit 2) are formed at positions immediately below the PG electrodes in the z direction.

The gate oxide layer is made of SiO₂, and a thickness thereof in the z direction is set to 10 nm.

The BG electrodes are each formed of an aluminum (Al) electrode and as illustrated in FIG. 5(c), three BG electrodes are arranged to be spaced apart from each other in the x direction so that one BG electrode is arranged at a middle position of two BG electrodes on both end sides. The length (L_{BG}) of each of the BG electrodes in the x direction is set to 36 nm.

Further, the PG electrodes are each formed of an aluminum (Al) electrode and as illustrated in FIG. 5(c), two PG electrodes are arranged in the x direction so that one PG electrode is arranged at a middle position of two adjacent BG electrodes. The length (L_{PG}) of each of the PG electrodes in the x direction is set to 48 nm.

Further, those PG electrodes and BG electrodes are arranged so as to be spaced apart from each other at intervals of 6 nm in the x direction (see FIG. 5(c)).

Each portion positioned above the trench groove of the P-type support layer is covered with any insulating material.

Further, in this simulation test, as a condition of the static magnetic field to be applied to the quantum bit, a magnetic field condition of up to about 0.1 T is assumed.

In the test target device set as described above, through quantum-mechanical exchange interaction, a SWAP operation of flipping the quantum state obtained by the two-electron state (spin-up and spin-down) in the two quantum bits of bit 1 and bit 2 formed in the SOI layer (for example, flipping from the state of |0>|1> to the state of |1>|0>) can be executed.

### <Simulator>

The simulation test was carried out through use of a simulator (see Reference Literature 1 with details) obtained by implementing a function of analyzing a quantum state of a semiconductor-type quantum bit on a TCAD simulator that is independently developed by the applicant.
Reference Literature 1: H. Asai et al., EDTM Tech. Dig. 2021, p. 238.

### <Verification of Variations in Exchange Interaction>

For each of the test target device and a comparative test target device obtained by forming no N-type support layer (N dope) in the test target device and setting a region in which the N-type support layer was to be formed as a part of the P-type support layer (P substrate), through voltage control between the PG electrode and the BG electrode, bit 1 and bit 2 were formed in the SOI layer. Further, the exchange interaction (Jₑₓ) between those two quantum bits was calculated through use of the simulator.

In this case, for the test target device, the calculation was carried out under two conditions of an “N/P substrate” condition in which no voltage was applied to the back gate electrode and an “N/P substrate & V_{sub}=0.3 V” condition in which a voltage of 0.3 V was applied to the back gate electrode. For the comparative test target device, the calculation was carried out under a “P substrate” condition in which no voltage was applied to the back gate electrode.

Further, for each condition, the calculation was carried out under three conditions of a basic condition (ΔW=0) in which the width W illustrated in FIG. 5(b) was 48 nm and size change conditions (ΔW=−3 nm and ΔW=+3 nm) in which two types of size changes of ±3 nm were added to the width W.

As a specific method of calculating the exchange interaction, first, in accordance with Reference Literature 1, wave functions of electrons in bit 1 and bit 2 were obtained so that the electron distribution in the quantum dot region in the SOI layer and a carrier region outside of the quantum dot region became self-consistent.

Next, through use of the obtained wave functions, the exchange interaction between bit 1 and bit 2 was calculated based on a method similar to the Heitler-London method in molecular orbital. This calculation method was carried out by calculating the exchange interaction between bit 1 and bit 2 by a procedure on the following items (a) and (b) based on Reference Literature 2 below. The energy difference between the spin singlet state and the triplet state in the item (b) corresponds to the exchange interaction.

(a) The wave function of the orbital for the electron to enter is extracted for each of bit 1 and bit 2. (b) The Hamiltonian of the two-electron state in consideration of spin is formed, and the energy difference between the spin singlet state and the triplet state is calculated from the diagonalization thereof.
Reference Literature 2: Physical Review B, 59 2070 (1999).

FIG. 6 shows calculation results of the exchange interaction (Jₑₓ) for the “P substrate” condition in the comparative test target device and the “N/P substrate” condition and the “N/P substrate & V_{sub}=0.3 V” condition in the test target device.

As shown on the left side of FIG. 6, in the “P substrate” condition in the comparative test target device, as compared with the exchange interaction of the basic condition (ΔW=0), the exchange interactions in the two size change conditions (ΔW=−3 nm, ΔW=+3 nm) have fluctuations of ±35%.

Meanwhile, as shown in the middle of FIG. 6, in the “N/P substrate” condition in the test target device, the width of the fluctuations is reduced to ±20%. Further, as shown on the right side of FIG. 6, in the “N/P substrate & V_{sub}=0.3 V” condition in the test target device, the width of the fluctuations is reduced to ±1%.

As described above, FIG. 6 shows that the width of the fluctuations of the exchange interaction due to the influence of the two size change conditions (ΔW=−3 nm, ΔW=+3 nm) is changed so as to be narrowed in the order of the left side, the middle, and the right side, and further the exchange interactions obtained under the size change conditions come closer to Jₑₓ of the basic condition (ΔW=0) in the stated order.

That is, the results represent that, in the test target device, the change of the exchange interaction (Jₑₓ) due to the fluctuations of the width W can be suppressed by introducing the “N/P substrate,” and further this suppression effect remarkably appears through voltage application to the back gate electrode.

### <Verification of Fidelity>

As described with reference to FIG. 6, large fluctuations in exchange interaction are observed due to a slight dimensional error of 3 nm. Accordingly, the influence of the fluctuations in exchange interaction to the device is a big concern.

In this simulation test, with respect to the quantum computing operation in a device having a correct dimension serving as a reference, how much quantum computing operations of a device having a dimensional error became incorrect was evaluated by an index of “gate operation fidelity F_{G}” represented by the following expression (1).

$$\begin{matrix}[ Math . 1 ] & \\ {F}_{G} = Tr [ U {ρ}_{0} {U}^{†} K {ρ}_{0} {K}^{†} ] & ( 1 )\end{matrix}$$

In the expression (1), ρ₀ represents a density matrix for showing an initial two-electron state, U represents a quantum computing operation in a device having a correct dimension, and K represents a quantum computing operation in a device having a dimensional error. Further, in this case, the influence of decoherence is ignored, and the fidelity of the quantum gate operation with respect to a quantum-mechanical pure state is evaluated.

In the expression (1), the fidelity Fa takes a value of from 0 to 1. K=U (no dimensional error) represents an ideal gate operation, and the fidelity F_{G} becomes 1.

A method of calculating the fidelity F_{G} is described.

First, the test target device and the comparative test target device that are calculation targets are each a two-qubit spin quantum bit device, and the Hamiltonian of the two-qubit state of the two-qubit spin quantum bit device can be written as the following expressions (2) to (4).

$$\begin{matrix}[ Math . 2 ] & \\ \hat{H} = {\hat{H}}_{Z} + {\hat{H}}_{J} & ( 2 )\end{matrix}$$

$${\hat{H}}_{Z} = - \frac{1}{2} g μ {B}_{z , 1} {σ}_{z , 1} - \frac{1}{2} g μ {B}_{z , 2} {σ}_{z , 2} \qquad ( 3 )$$

$${\hat{H}}_{J} = - \frac{1}{4} J ( t ) ( {σ}_{x , 1} {σ}_{x , 2} + {σ}_{y , 1} {σ}_{y , 2} + {σ}_{z , 1} {σ}_{z , 2} ) \qquad ( 4 )$$

In those expressions, “g” represents a g factor of the electron in the quantum dot, “μ” represents Bohr magneton, B_{z,i} represents a magnetic field to be applied to an i-th (“i” is 1 or 2) quantum bit, σ_{x,i}, σ_{y,i} and σ_{z,i} represent Pauli operators acting on the i-th (“i” is 1 or 2) quantum bit and J represents exchange interaction between two quantum bits.

Next, the SWAP operation in the two-qubit spin quantum bit device is ideally achieved when, in the Hamiltonian, a voltage pulse is applied to the barrier gate (BG) electrode for a certain time period “τ” (=h/2J₀) so that J(t)=J₀ is satisfied.

That is, in this case, the two-qubit quantum state is changed so that |0>|1> representing that bit 1 is the 0 state and bit 2 is the 1 state is exchanged (swapped) to |1>|0> representing that bit 1 is the 1 state and bit 2 is the 0 state.

From this relationship, the SWAP operation of the device having a correct dimension serving as a reference can be defined by applying an ideal square-wave pulse voltage to the barrier gate (BG) electrode for the time period of τ=h/2J₀ when the initial two-qubit quantum state is |0>|1>.

At this time, the quantum computing operation K in the device having a dimensional error can be expressed through use of J₀ of the device having a correct dimension serving as a reference and J₀′ of the device having a dimensional error, and the expression (1) for the fidelity F_{G} finally results in a simple expression expressed by the following expressions (5) and (6).

$$\begin{matrix}[ Math . 3 ] & \\ {F}_{G} = 0.5 ( 1 - cos ( {J}_{0}^{′} {τ}_{0} / ℏ ) ) & ( 5 )\end{matrix}$$

$${τ}_{0} = πℏ / {J}_{0} \qquad ( 6 )$$

In view of the above, the gate operation fidelity F_{G} for the test target device and the comparative test target device was obtained by (1) calculating, through use of the simulator, the exchange interaction J₀ obtained by applying a pulse voltage to the barrier gate (BG) electrode for the time period of τ=h/2J₀ at the time of having a correct dimension (W=0), (2) calculating, through use of the simulator, the exchange interaction J₀′ obtained by applying a pulse voltage to the barrier gate (BG) electrode for the time period of τ=h/2J₀ at the time of having a dimensional error, and (3) performing calculation by the expressions (5) and (6) through use of the obtained exchange interactions J₀ and J₀′. This Fa can be referred to as “SWAP operation fidelity” because the operation to be executed is the SWAP operation.

The calculation of the SWAP operation fidelity was carried out under four conditions of the “P substrate” condition and a “P substrate & V_{sub}=0.3 V” condition in the comparative test target device and the “N/P substrate” condition and the “N/P substrate & V_{sub}=0.3 V” condition in the test target device. The “P substrate & V_{sub}=0.3 V” condition is a condition of applying a voltage of 0.3 V to the back gate electrode in the comparative test target device.

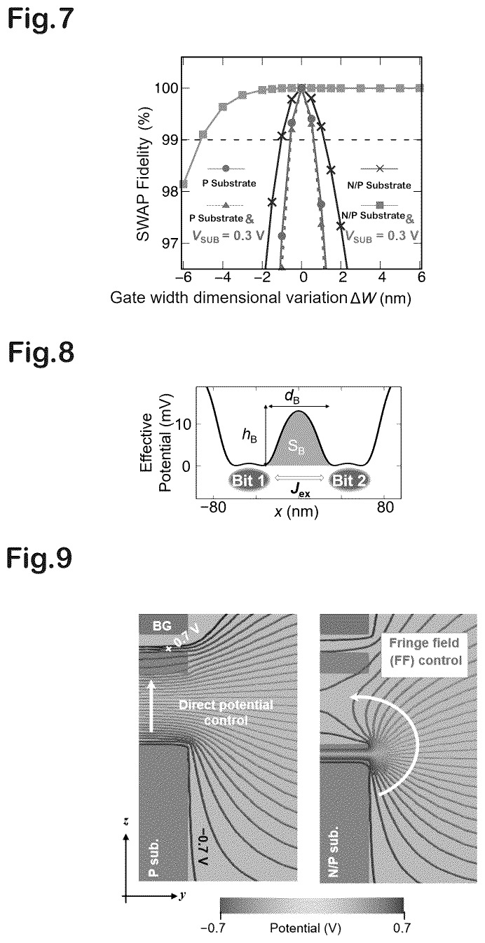

FIG. 7 shows calculation results of the SWAP operation fidelity.

In general, the fidelity of 99% or more is a reference desired for quantum error correction (see Reference Literature 3). As shown in FIG. 7, in the “N/P substrate” condition in the test target device, as compared with the “P substrate” condition and the “P substrate & V_{sub}=0.3 V” condition in the comparative test target device, the SWAP operation fidelity of 99% or more can be achieved in a wider range of the dimensional variation (ΔW).

In addition, in the “N/P substrate & V_{sub}=0.3 V” condition in the test target device, as compared with other conditions, the SWAP operation fidelity of 99% or more can be achieved in a significantly wider range of the dimensional variation (ΔW), and the SWAP operation fidelity is dramatically improved.

In the “N/P substrate & V_{sub}=0.3 V” condition in the test target device, the dimensional variation (ΔW) at the fidelity of 99% or more is permitted in a range of ±5 nm, which greatly exceeds 0.9 nm which is a gate dimension 3σ variation of the latest semiconductor manufacturing technology (a target value of IEEE International Roadmap for Devices and Systems (IRDS) 2022), and large-scale quantum bit integration exceeding 1,000,000 quantum bits is possible.

Such dramatical improvement of the SWAP operation fidelity through voltage application to the back gate electrode is not observed in the comparative test target device, and hence it is clear that the improvement receives an influence of the “N/P substrate” condition in the test target device.
Reference Literature 3: A. G. Fowler et al., Phys. Rev. A, 86, 032324 (2012).

### <Consideration of Characteristic Variation Suppression Principle>

In response to those simulation results, the reason why the characteristic variation caused by the influence of the dimensional variation was able to be suppressed by the “N/P substrate” condition and the “N/P substrate & V_{sub}=0.3 V” condition in the test target device was further verified.

First, the cause of occurrence of the characteristic variation due to the influence of the dimensional variation (ΔW) is considered.

Exchange interaction between two quantum bits in a semiconductor-type two-qubit device receives the influence of a potential barrier area between the two quantum bits as shown in FIG. 8. FIG. 8 is an explanatory graph for showing the relationship between the exchange interaction between the two quantum bits and the potential barrier area.

When the width of the SOI layer has a dimensional variation (ΔW), the energy levels of the two quantum bits change. This change causes changes in both of a potential barrier height (h_{B}) between the two quantum bits and a distance (d_{B}) between the bottom of the potential of one quantum bit and the bottom of the potential of the other quantum bit at the same time, and thus causes a change in the potential barrier area (S_{B}) which is determined mainly by the potential barrier height (h_{B}) and the distance (d_{B}). The change in the potential barrier area (S_{B}) causes an exponential change in the exchange interaction between the two quantum bits.

That is, the dimensional variation (ΔW) causes a variation (ΔS_{B}) in the potential barrier area and further causes an exponential change in the exchange interaction between the two quantum bits.

This finding means that, in other words, even when there is a dimensional variation (ΔW), as long as the variation in the potential barrier area (ΔS_{B}) can be suppressed, the change in the exchange interaction between the two quantum bits can be suppressed.

At the time of obtaining the calculation results shown in FIG. 8, in order to extract an effective potential distribution between the two quantum bits, a potential Y was weighted by a density p of the electron in the quantum dot, and an effective one-dimensional potential distribution Ψ_{1D}(x) in a direction (x direction) along the bit string of the quantum bits was obtained.

The calculation results shown in FIG. 8 are calculation results obtained by obtaining, by the following expression (8), the effective one-dimensional potential distribution Ψ_{1D}(x) weighted by a two-dimensional electron density (ρ_{2D}(y, z)) standardized by the following expression (7), and then calculating, from the obtained effective one-dimensional potential distribution Ψ_{1D}(x), the potential barrier height (h_{B}) between the two quantum bits, the distance (d_{B}) between the bottom of the potential of one quantum bit and the bottom of the potential of the other quantum bit, and the potential barrier area (S_{B}).

$$\begin{matrix}[ Math . 4 ] & \\ {ρ}_{2 D} ( y , z ) = \frac{\int ρ ( x , y , z ) dx}{\int \int \int ρ ( x , y , z ) dxdydz} & ( 7 )\end{matrix}$$

$${Ψ}_{1 D} ( x ) = \int \int {ρ}_{2 D} ( y , z ) Ψ ( x , y , z ) dydz \qquad ( 8 )$$

Subsequently, the verification is advanced with reference to FIG. 9 for the point that, even when there is a dimensional variation (ΔW), as long as the variation in the potential barrier area (ΔS_{B}) can be suppressed, the change in the exchange interaction between the two quantum bits can be suppressed. FIG. 9 is a diagram for showing potential distributions in the y-z plane in the test target device and the comparative test target device obtained by the previous calculation.

In the comparative test target device, as shown on the left side of FIG. 9, it is found that the quantum bit region of the SOI layer receives linear potential control from the P-type support layer. Meanwhile, in the test target device, as shown on the right side of FIG. 9, it is found that the quantum bit region of the SOI layer receives potential control in the form of being routed around in the internal direction of the upper surface from a corner portion of an outer edge of an upper surface of the N-type support layer. This state is considered to be caused by the fringe electric field (Fringe field) generated by arranging the N/P substrate, which provides potential modulation to the quantum bit region.

That is, the fringe electric field is generated in a form of, similarly to the potential distribution shown in FIG. 9, being routed around in the internal direction of the upper surface from the corner portion of the outer edge of the upper surface of the N-type support layer, and thus the fringe electric field can be considered to provide potential modulation to the quantum bit region in this form.

In addition, the fringe electric field is considered to contribute to suppression of the variation (ΔS_{B}) in the potential barrier area. That is, the intensity of the fringe electric field has a relationship with the width W to change in accordance with the width W, and hence the fringe electric field compensates for the potential barrier modulation so that the potential barrier area variation (ΔS_{B}) caused by the dimensional variation (ΔW) of the width W comes closer to the potential barrier area (S_{B}) serving as a reference.

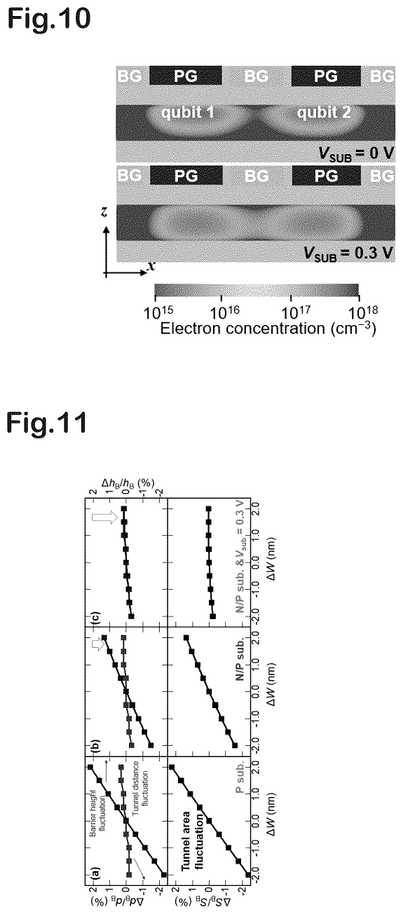

Subsequently, the reason why the SWAP operation fidelity is dramatically improved in the “N/P substrate & V_{sub}=0.3 V” condition is verified. FIG. 10 shows the electron density distribution in bit 1 and bit 2 based on the wave functions of the electrons in bit 1 and bit 2, which have been obtained at the time of previous calculation of the exchange interaction.

As shown on the upper side of FIG. 10, in the “N/P substrate” in which no voltage is applied to the back gate electrode, each of the electrons in bit 1 and bit 2 is attracted to the plunger gate electrode side, and thus an angular electron density distribution that is biased to the side of the interface with the gate oxide layer is obtained. Meanwhile, in the “N/P substrate & V_{sub}=0.3 V” condition, each of the electrons in bit 1 and bit 2 is attracted to the back gate electrode side, and thus an electron density distribution in a mode in which the electron is moved from the upper surface side of the SOI layer to the center is obtained.

In this manner, an action of compensating for the potential barrier modulation in the form of being routed around in the internal direction of the N-type support layer by the “N/P substrate” and an action of eliminating the bias of the electron density distribution in the thickness direction (z direction) of the N-type support layer act in superimposition. Thus, it is considered that the influence given by the dimensional variation (ΔW) of the width W to the potentials of bit 1 and bit 2 is furthermore minimized.

Finally, FIG. 11 shows the relationship between ΔW and each of Δd_{B}, Δh_{B} and ΔS_{B} normalized by d_{B}, h_{B} and S_{B}, respectively.

As shown in FIG. 11, in the “P substrate” condition (P sub.) in the comparative test target device, as the variation in ΔW becomes larger, Δh_{B}/h_{B} and ΔS_{B}/S_{B} are greatly changed. Meanwhile, in the “N/P substrate” condition (N/P sub.) in the test target device, the changes in Δh_{B}/h_{B} and ΔS_{B}/S_{B} can be suppressed. Particularly, in the “N/P substrate & V_{sub}=0.3 V” condition (N/P sub. & V_{sub}=0.3 V), the changes in Δh_{B}/h_{B} and ΔS_{B}/S_{B} can be remarkably suppressed.

Those results match the verification results so far and are solid evidence for supporting the effectiveness of the present invention.

### REFERENCE SIGNS LIST

1, 21, 31 support substrate
2, 22, 32 fringe electric field forming layer
3, 23, 33 buried oxide layer
4, 24, 34 quantum dot semiconductor layer
5, 25, 35 back gate electrode
10 semiconductor-type quantum bit device
20 semiconductor-type spin quantum bit device
27a, 27b, 27c, 37a, 37b, 37c barrier gate electrode
28a, 28b, 38a, 38b plunger gate electrode
29 buried magnet layer
30 semiconductor-type charge quantum bit device

1. A semiconductor-type quantum bit device, comprising at least:
a support substrate formed of a first conductivity type semiconductor layer;
a fringe electric field forming layer formed on the support substrate, the fringe electric field forming layer being formed of any one of a second conductivity type semiconductor layer and a metal layer, the second conductivity type semiconductor layer having a conductivity type different from a conductivity type of the first conductivity type semiconductor layer and the metal layer forming a Schottky barrier with the support substrate;
a buried oxide layer formed on the fringe electric field forming layer; and
a quantum dot semiconductor layer which is formed on the buried oxide layer and in which quantum dots are formed.

2. The semiconductor-type quantum bit device according to claim 1, further comprising a back gate electrode configured to apply a voltage to the support substrate.

3. The semiconductor-type quantum bit device according to claim 1, wherein the buried oxide layer has a thickness of from 10 nm to 100 nm.

4. The semiconductor-type quantum bit device according to claim 1, wherein the quantum dot semiconductor layer is formed into an elongated band shape in a top view, and the elongated band has a width in a transverse direction of 100 nm at longest.

5. The semiconductor-type quantum bit device according to claim 1, wherein the quantum dot semiconductor layer has a thickness of from 2.5 nm to 50 nm.

6. The semiconductor-type quantum bit device according to claim 1,
wherein the support substrate has a first conductivity type impurity concentration of 1×10¹⁹ cm⁻³ or more, and
wherein the fringe electric field forming layer is formed of the second conductivity type semiconductor layer and has a second conductivity type impurity concentration of 1×10¹⁹ cm⁻³ or more.

7. The semiconductor-type quantum bit device according to claim 6,
wherein the support substrate is formed of Si, and
wherein the second conductivity type semiconductor layer is formed of Si.

8. The semiconductor-type quantum bit device according to claim 1, wherein the quantum dot semiconductor layer is formed of any one of Si, SiGe and Ge.

9. The semiconductor-type quantum bit device according to claim 1, wherein the buried oxide layer is formed of any one of SiO₂ and GeO₂.

10. The semiconductor-type quantum bit device according to claim 1, further comprising at least:
a structure unit in which three barrier gate electrodes and two plunger gate electrodes are formed above the quantum dot semiconductor layer through a gate insulating layer, each of the two plunger gate electrodes being arranged between adjacent two of the three barrier gate electrodes so as to be spaced apart from the adjacent two of the three barrier gate electrodes, the quantum dots being formed at two positions opposed to the two plunger gate electrodes of the quantum dot semiconductor layer; and
a static magnetic field applying unit configured to apply a static magnetic field to the quantum dots.
